(19) United States
(12) Patent Application Publication
(10) Pub. No.: US 2002/0158299 A1
(43) Pub. Date: Oct. 31, 2002

(54) Mask configurable smart power circuits - applications and GF-NMOS devices

(76) Inventors: Maria Ines Castro Simas, Lisboa (PT); Saulo Finco, Rodovia (BR); Antonio Pedro Casimiro, Lisboa (PT); Pedro Mendonca Santos, Lisboa (PT); Frank Herman Behrens, Rodovia (BR); Carlos Mammana, Rodovia (BR)

Correspondence Address: ROTHWELL, FIGG, ERNST & MANBECK, P.C., 1425 K STREET, N.W., SUITE 800, WASHINGTON, DC, 20005, US

(21) Appl. No.: 09/915,571

(22) Filed: Jul. 27, 2001

Related U.S. Application Data
(63) Continuation of application No. 09/720,622.
Application No. 09/720,622 is a 371 of international application No. PCT/PT00/00003, filed on Apr. 28, 2000.

(30) Foreign Application Priority Data
Apr. 28, 1999 (PT) 102297

(51) Int. Cl. H01L 29/00

(52) U.S. Cl. 257/499

(57) ABSTRACT

A mask-configurable smart power integrated circuit includes arrays of associated NMOS FETs that perform functions such as control, amplification and sampling of output variables. The arrays include NMOS basic cells using FET arrangements such as LDD, LDSD-NMOS, LDMOS, or N-channel DMOS. The smart power integrated circuits are useful to provide switching to power cells and drives, and protection from overload conditions.

### SUMMARY OF THE INVENTION

This invention is related to important improvements in Smart Power designs using arrays based on a unique NMOS cell type in matrix arrangements suitable to implement generic functions required by power control blocks. This technique enables low cost semicustom designs and new ICs configuration strategies of easy industrial implementation towards Smart Power using standard CMOS technologies aimed at digital integrated circuits, without any additional processing steps. The same methodology can also be applied to sophisticated Smart Power technologies, for fast prototyping.

### INVENTION BACKGROUND

Smart power progress deals with development of new technological processes, the capabilities of which are dependent on the correct characterisation and availability of power devices, and required digital and analogue libraries. This calls for sophisticated and costly technological processes. These sophisticated technologies have produced various types of semiconductor devices, such as N-MOS, P-MOS, HV-NMOS (High-voltage NMOS), HV-PMOS (High-voltage PMOS) Field-Effect Transistors; NPN, PNP, HV-PNP, HV-NPN Bipolar Junction Transistors—BJT, Zener and rectifier Diodes, IGBTs and MOS Thyristors, just to name a few.

A world wide huge effort is being carried out to find solutions that are compatible with CMOS technologies.

None of these approaches have yet succeeded in using a unique cell type to implement the functions required by the Power Control blocks in Smart Power ICs using a standard CMOS fully compatible device.

A different approach was selected by the applicants to assess the viability of using a low cost, submicron, standard CMOS technology, with one polysilicon layer, N-well and double metalization, aimed at high speed, high integration density and low voltage (5 V) customised digital circuits, towards very low cost smart power ICs, using modified structures aimed at high-side and low-side switch configurations and lateral NMOS based optimised switching cells.

The following list includes all the references known to the applicants, which they consider to be representative with regard to this subject and which in a way are also considered as being the background to the invention.

### References

U.S. Patent Documents

5,386,136 1/1995 Richard Williams et al. “Lightly-Doped Drain MOSFET With Improved Breakdown Characteristics”.

Other Publications

H. Ballan and M. Declercq “High Voltage Devices and Circuits in Standard CMOS Technologies”, Kluwer Academic Publishers, Dordrecht, The Netherlands, 1999.

B. J. Baliga “An Overview of Smart Power Technology”, IEEE Trans. on Electronic Devices, Vol. 38, n.7, pp. 1568-1575, July 1991.

W. Pribyl, “Integrated Smart Power Circuits Technology, Design and Application”, in Proceedings of the 22nd European Solid-State Circuits Conference, ESSCIRC '96, Neuchâtel, Switzerland, Sep. 17-19, 1996

A. B. Murati, F. Bertotti and G. A. Vignola (Eds.), “Smart Power ICs—Technologies and Applications”, Springer, Berlin, 1996.

“Smart Power Markets and Applications”, Electronic Trend Publications, 1996.

A. G. M. Dolny, O. H. Schade, B. Goldsmith, and L. A. Goodman, “Enhanced CMOS for analog-digital power IC applications,” IEEE Trans. Electron Devices, vol. ED-33, pp. 1985-1991, 1986.

B. Z. Parpia, C. A. T. Salama and R. A. Hadaway, “Modelling and characterisation of CMOS-compatible high-voltage device structures”, IEEE Trans. Electron Devices, vol. ED-34, pp. 2335-2343, 1987.

C. T. Efland, T. Keller, S. Keller and J. Rodriguez, “Optimised complementary 40 V power LDMOS-FETs using existing fabrication steps in submicron CMOS technology”, in IEDM Tech. Dig., pp. 399-402, 1994.

S. Finco, F. H. Behrens, M. I. Castro Simas, “A Smart Power IC for DC-DC Power Regulation”, in Proceedings IEEE Industrial Applications Society 27^{th} Annual Meeting, IAS '92, pp. 1204-1211, Houston, Teas, U.S.A., October 1992.

M. I. Castro Simas, J. Costa Freire, S. Finco, F. H. Behrens, “Modeling and Characterization of LDD and LDSD NMOS Transistors” in Proceedings IEEE Industrial Applications Society 28^{th} Annual Meeting, IAS '93, pp. 1183-1189, Toronto, Ontario, Canada, October 1993.

### DESCRIPTION AND APPLICATION OF THE INVENTION

To assess the viability of Smart Power fast-prototyping a low cost, submicron, standard CMOS technology, with one polysilicon layer, N-well and double metalization, aimed at high speed, high integration density and low voltage (5 V) customised digital circuits, was selected, towards very low cost smart power ICs, using modified structures aimed at high-side and low-side switch configurations and lateral NMOS based optimised switching cells (namely the GSLDD/GSLDSD-NMOS). Appropriate associations of power devices, namely GSLDSD, LDSD or other floating transistors, together with passive elements integrated or not in the same monolithic circuit, can also be repeated to form arrays, that can be associated in a matrix arrangement, which are easily programmable by convenient metal masks according to the required functionality.

Furthermore, engineering developments of adequate circuits to implement functions required to drive and to protect these devices and to sense and to control according to specific power regulation or amplification topologies, showed that it was possible to build new blocks, all resorting to a unique NMOS cell type, which is mainly a floating transistor that can either be the GSLDSD, or the LDSD, or another high-pass transistor, such as the LDMOS. CMOS standard technologies were used to prove the viability of this approach. Power devices and drive circuitry blocks aimed at an efficient drive, such as, NMOS level shifters and voltage references, NMOS rectifiers, NMOS based charge-pumps, NMOS based bootstraps, and an NMOS current generator were implemented using a programmable NMOS structure based matrix, only using the top metal mask for the required interconnections.

These optimized NMOS devices, associated in special structures in a matrix arrangement and included in an already matured CMOS technology, enable reliable solutions at low cost. Furthermore, Electronic Design Automation (EDA) tools are already available, allowing a short design cycle with high probability of error-free implementation, taking advantage of automatic placement and routing, system and circuit simulators, standard cells libraries, etc.

Therefore, this methodology shows to be extremely suitable for Smart Power Semicustom designs and thus for Smart Power fast prototyping using standard CMOS technologies without any additional processing steps. Moreover, this concept can also be applied to dedicated technologies, when customised ICs are in scope, in order to obtain off-the-shelf solutions for low series production cost and short production cycle.

### SCOPE OF THE INVENTION

This invention concerns new strategies for Smart Power Semicustom design and thus, fast-prototyping, using associations of a unique cell type as an elementary array in a matrix arrangement conveniently designed to be easily programmed using only top metal masks, according to the required functionality, in order to implement all the required topologies for commutation, drive, protection, amplification, sensing and control, capable to handle high voltage signals, as well as interfaces with microprocessors, fault detection and process monitoring.

Thus, circuits based on NMOS Structures are obtained, the topography of which can be designed in order that they may be obtained using suitable interconnections established in and between basic Cell Arrays that are configurable by means of the top metal layer(s), which bestow unique characteristics for Smart Power fast prototyping not only using CMOS technologies but also resorting to Power Integration dedicated technologies.

Smart Power fast-prototyping will have immediate application for low and medium power applications, namely for automobile, robotic, portable telecommunications and medical equipment industries, which are areas that require a high level of reliability and compactness.

### SUBJECT AND AIM OF THE INVENTION

The present invention relates to the design and implementation of circuits to perform the functions of switching, driving, controlling, amplification, sensing and protection within monolithic Smart Power systems by simply using NMOS Structures:

(a) to provide cell libraries of programmable matrix arrangements based on NMOS structures, in order to implement the required functions towards power conversion and power amplification, by means of convenient metal layers interconnections;

(b) to provide circuit topologies, that implement required functions, handling high voltages, to control, drive, sense and protect devices, resorting, exclusively, to NMOS structures;

(c) to optimise LDSD and LDD NMOS transistors, increasing breakdown voltage up to 50V, using a standard CMOS technology, through the use of optimised NMOS devices (GSLDD and GSLDSD), thus, enabling to extend the range of voltages well beyond the recognised limits for conventional technologies;

(d) to decrease substantially low series production cost;

(e) to reduce turn-around production cycle without reducing reliability; and

(f) to enable the reuse of functional blocks.

### ADVANTAGES AND IMPROVEMENTS IN RELATION TO EXISTING METHODS,

### MATERIALS OR PRODUCTS

The invention presented herein covers Arrays and Matrices of basic cells: which use NMOS Structures to perform the functions which are generally required for power control, amplification, conversion and switching; and NMOS devices that are optimised in respect of the voltage withstood in the cut-off state, namely GSLDD/GSLDSD NMOS transistors.

The advantages of this invention are the following:

it permits the use of standard technologies which are more simple or less complex than the ones usually used for creating high-voltage power devices and carrying out power control functions, by simply using NMOS Structures which use lightly doped diffusions in the formation of the Drain and Source terminals;

it permits the use of a single basic electric model of semiconductor Structures for simulating devices and circuits;

it makes Smart Power Integration compatible with standard CMOS technologies without any additional processing steps;

it makes the mass production of Microsystems compatible with conventional CMOS technologies without any additional processing steps, in accordance with technological trends;

it gives potential to many standard CMOS processes existing on the market in order to implement Smart Power Circuits by simply adding power control circuit libraries to the libraries which already exist;

it permits the creation of semi-custom Smart Power Integrated Circuits, which are easily configurable by means of the top metal layer(s) using conventional CMOS technological processes available for manufacturing semi-custom digital circuits;

it gives potential to many dedicated Smart Power technologies in order to make it possible to manufacture semi-custom Smart Power Circuits, which are easily configurable by means of the top metal layer(s), by simply creating power control circuit libraries;

it makes it possible to fast prototype Smart Power Integrated Circuits using any CMOS technology, where a floating NMOS device is available;

it makes it possible to obtain optimised geometry for high-voltage transistors which is compatible with standard CMOS technologies, and it can also be applied to wider ranges of voltages than the ones usually established for these technologies.

### BRIEF DESCRIPTION OF THE DRAWINGS

The following description refers to the drawings, which form an integral part thereof and are intended to make it easier to understand the invention, without any restrictive character. Thus:

FIGS. 1 to 4 show generic switching cells to implement power devices topologies.

FIG. 5 shows the general matrix arrangement of switching structures, pointing out the spatial layout of the structures and arrays, the positioning of the control signal interconnection channels, the power interconnection channels and the position of the pads.

FIG. 6 shows the details of the matrix, paying special attention to connection contacts of the array, indicating the metal2 tracks over the structures close to the pads.

FIG. 7a) shows the control signal interconnection channels, indicating the network of vias (metal1/metal2 connections), metal1 tracks and polysilicon resistors;b) cut AA′.

FIG. 8 shows an elementary NMOS structure consisting of LDSD transistors placed side by side.

FIG. 9 shows a cross-section of the proposed optimised elementary cell based on GSLDD/GSLDSD NMOS transistors.

FIG. 10 shows (a) a rectifier diode and related characteristic curve I(V); (b) a Zener diode and the respective characteristic curve I(V); (c) a rectifier diode in series with a Zener diode and the respective characteristic curve I(V).

FIG. 11 shows an integrating control circuit of the circuits, which emulate the Zener diode and the rectifier diode.

FIG. 12 shows the reconfiguration of an NMOS Structure, based on LDSD NMOS transistors, which emulates the behaviour of the floating Zener Circuit of FIG. 10b).

FIG. 13 shows the reconfiguration of an NMOS Structure, based on LDMOS transistors, which emulates the behaviour of the floating Zener Circuit of FIG. 10b).

FIG. 14 shows the reconfiguration of an NMOS Structure, based on LDSD NMOS transistors, which emulates the behaviour of the rectifier diode—Zener diode series association of FIG. 10c).

FIG. 15 shows the reconfiguration of an NMOS Structure, based on LDMOS transistors, which emulates the behaviour of the rectifier diode—Zener diode series association of FIG. 10c).

FIG. 16 shows the reconfiguration of an NMOS Structure, based on LDSD NMOS transistors, which emulates the behaviour of the rectifier diode of FIG. 10 a).

FIG. 17 shows the reconfiguration of an NMOS Structure, based on LDMOS transistors, which emulates the behaviour of the rectifier diode of FIG. 10a).

FIG. 18 shows a classic level-shifter circuit, as disclosed in literature, which uses PMOS (or PNP Bipolar type), high-voltage, high-side transistors.

FIG. 19 shows a level-shifter circuit using only LDSD NMOS transistors. This topology dispenses with the use of high-voltage PMOS (or PNP bipolar transistors) in the high-side position.

FIG. 20 shows a level-shifter circuit using only LDMOS transistors. The addition of the diode DR should be noted when compared with the topology of FIG. 19.

FIG. 21 shows a level-shifter circuit working as a continuous voltage level shifter. In this configuration the circuit operates as a HV-derived auxiliary continuous voltage.

FIG. 22 shows: a) a typical capacitive charge-pump which acts as a voltage doubler, b) the voltage waveform over the capacitor C_{Tq}.

FIG. 23 shows a typical capacitive charge-pump which acts as a voltage tripler.

FIG. 24 shows a charge-pump which acts as a voltage doubler, which can be implemented using NMOS structures.

FIG. 25 shows a typical capacitive charge-pump which acts as a voltage tripler, which can be implemented using NMOS structures.

FIG. 26 shows a capacitive charge-pump, which can be implemented using NMOS structures, which acts as a floating voltage source derived from the topology of FIG. 23, using a rectifier bridge at the output.

FIG. 27 shows an elementary circuit which can be implemented using NMOS structures, from which the charge-pump topologies, claimed as innovative, can be obtained.

FIG. 28 shows: a) a typical bootstrap circuit; b) time diagrams of the control, output and Gate voltages during MH turn-ON and turn-OFF transients.

FIG. 29 shows a bootstrap circuit which can be implemented using NMOS structures.

FIG. 30 shows: a) a NMOS based bootstrap circuit for power devices in a High-Side topology; and b) the respective waveforms during turn-ON and turn-OFF transients.

FIG. 31 shows a standard floating current source, for supplying current to a power device in a High-Side topology.

FIG. 32 shows a floating current source implemented resorting to NMOS Structures.

### DETAILED DESCRIPTION OF THE INVENTION

Below is a detailed description of the Matrices used in the scope of the invention, the elementary cells of which are based on optimised NMOS transistors. A detailed description of the devices optimisation technique based on a shifting of the polysilicon Gate mask is also given, which gives rise to the acronym GSLDD and GSLDSD NMOS for this type of optimised transistors that form part of the matter of the invention.

A detailed description of some of the Topologies of the proposed circuits is also given, based exclusively on NMOS Structures, as an integral part of the invention and to replace the conventional circuits necessary for driving the aforementioned power switching devices within Smart Power ICs power control block: Clippers; Clampers; Level Shifters; High-voltage Floating Drivers Charge-pump and Bootstrap.

1. Switching Cells

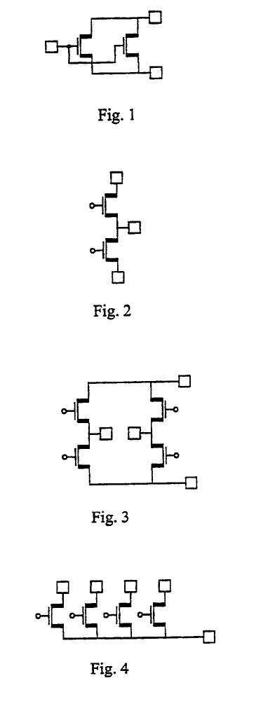

The switching cells are based on NMOS Structures available in a Matrix, which are configurable by means of the top metal layer(s). The possible associations are sufficiently versatile and permit to implement the most usual Switch Load Topologies: High-Side—FIG. 1; Low-Side—FIG. 1; Pass Element—FIG. 1; Push-Pull—FIG. 2; Half-Bridge—FIG. 2; Full-Bridge—FIG. 3; n-Phases—FIG. 4 and derived topologies.

The Matrices consist of NMOS Structures Arrays, which provide interconnection properties suitable for the intended purposes.

Although the Matrices and Arrays can generally use any isolated NMOS power transistor as an elementary cell, they are presented in this document as being based on NMOS transistors that can be implemented using conventional CMOS technologies.

1.A.1 NMOS Structures Matrix

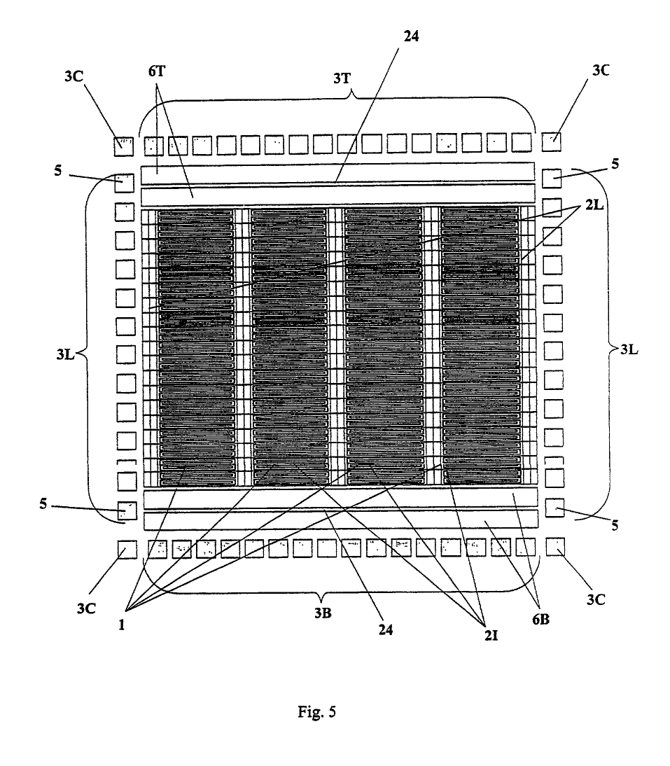

The Matrix (FIG. 5) consists of NMOS Structures Arrays (1) separated by control signal interconnection channels (interleaved, 21; lateral, 2L) and pads (top, 3T; bottom, 3B; lateral, 3L; corners, 3C). The number of stacked NMOS Structures, as well as the number of columns of Arrays, depends on the total amount of power for which the Matrix was designed.

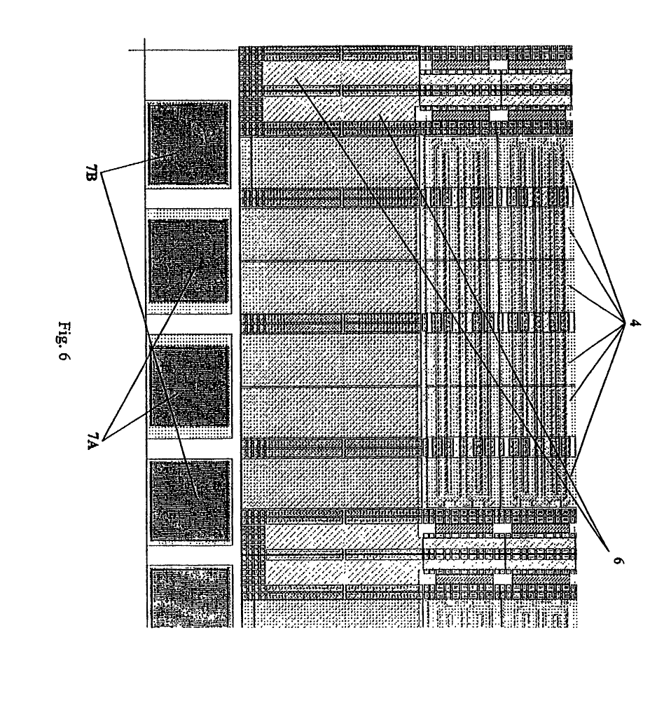

The interconnection of the Drains and Sources is made over the NMOS Structures arrays (1) (FIG. 5) by top layer metal tracks (metal2) (4) (FIG. 6), totalling six for each Structures array, in order to make the interconnections more flexible. The connection of the Drains and Sources between Structures of different arrays or to the lateral contacts next to the corners (5 and 3L) is implemented by means of a set of two or three connection tracks of the first metallisation (top, 6T; bottom, 6B) situated at the top and bottom of the Matrix (FIG. 6). The number of tracks depend on the size of the matrix.

The width of the NMOS Structures (1) is calculated so that the sum of the width of the control signal interconnection channels corresponds to the width necessary for positioning four pads (FIG. 6). Two out of these pads are used exclusively for power connections (7A) and the other two for control and/or power signals (7B). The number of contacts therefore depends on the number of arrays, eight for each array, four at the top and four at the bottom. The number of contacts at the sides of the matrix (FIG. 5-3L) is the same as the number of contacts at the bottom (3B) and the top (3T). The number of control signal interconnection channels (2I and 2L) (FIG. 5) is the same as the number of NMOS Structures arrays (1) plus one, so that both sides of the Matrix will have control signal interconnection channels (FIG. 5), thus allowing the control signal interconnection channels to be connected to the pads situated at both sides of the Matrix (3L).

1A.2 Interconnection Possibilities

The interconnection of the Structures to each other and to the pads is based on a minimum routing grid, depending on the minimum dimension of the technology and the specific restrictions of each matrix. The width of all the interconnection tracks, in both the first metallisation (metal1) and the second metallisation (metal2), is a multiple thereof.

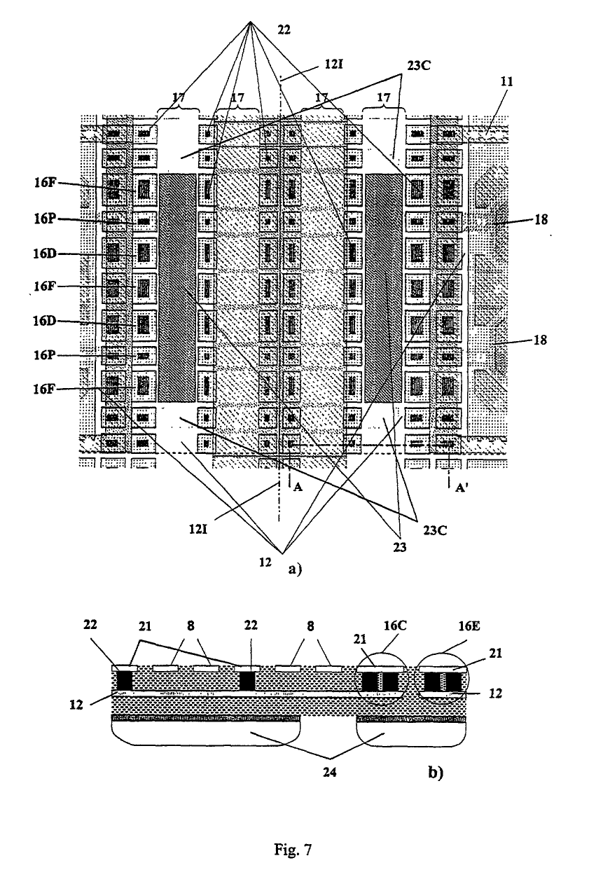

The control signal interconnection channels (FIG. 7) consist of metal1 tracks (12), which provide horizontal connections, and metal2 tracks (8), which provide vertical connections over pre-defined channels (17) (FIG. 7a)). The metal2/metal1 transition is made using the existing sets of vias (22). The vias are connections between the first and the second metallisation through thick or field oxide.

The interconnections by configuration of the pre-processed matrix are made by inserting metal2 rectangles between the sets of connections of the Structures (16E) and the sets of connections of the interconnection channels (16C), and the metal2 tracks (8) (FIG. 7b)), in order to make vertical connections for accessing: the top (6T) and bottom (6B) routing channels (FIG. 5); or the pads (3T, 3L or 3B); or to establish certain circuit topologies through the local interconnection of switching cells, aimed at low current levels.

In order to make the connection with the metal2 tracks in the vertical channels, a small path needs to be added horizontally in this metallisation from the closest set of vias (22).

The sets of connections existing in both, Structures (16E) and the interconnection channels (16C) (FIG. 7b)), consisting of metal1 rectangles (12) connected to metal2 (21) by various sets of vias (22), make it possible to connect the metal1 tracks (12) coming from the Gates (16P), Drains (16D), Sources (16F) and Guard Rings (11) of the NMOS Structures to the horizontal metal1 tracks (12) of the interconnection channels (FIG. 7a) and b)).

The metal1 tracks (12) of the interconnection channels are interrupted (12I) (FIG. 7a)) in order to give independent access to the two Structures adjacent to the channel. The interconnection channels provide both, horizontal interconnections of the elementary cells, in different arrays, and vertical interconnections of the elementary cells, within the same array.

In all the control channels, there are two polysilicon resistors (23) for each elementary cell. This polysilicon presents a higher resistance than that which is used for constructing the Gates of the transistors, with a typical value of 45Ω/□ (FIG. 7a)). The resistors (23) are inserted between different metal1 tracks (12) using a pair of poly2/metal1 contacts (23C) (FIG. 7a)).

The ground planes created by the P⁺ diffusion (24) (FIG. 5) make it possible to eliminate any closed loop, which may introduce noise. Likewise, the P⁺ diffusion tracks (24) (FIG. 7b)) underneath control interconnection channels are connected alternately to P⁺ tracks under the routing channels at the top (6T) and bottom (6B) of the matrix.

1A.3 The elementary NMOS Structure

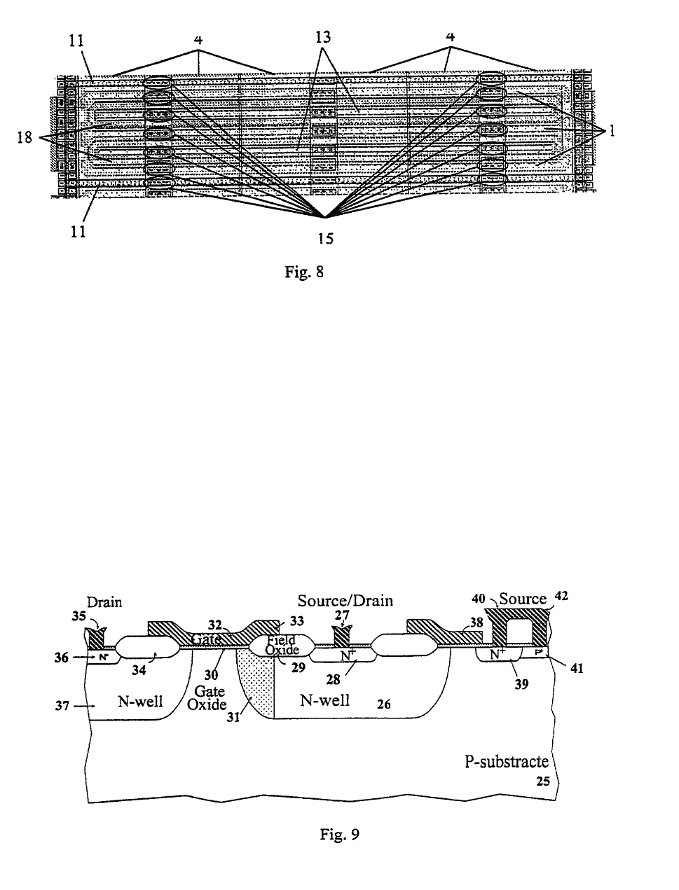

The elementary NMOS Structure consists of two LDSD (Lightly Doped Source and Drain) transistors placed side by side (FIG. 8), so that they can be used separately, sharing only the P⁺ diffusion guard ring (11) which also surrounds the whole (FIG. 8).

The internal connections to the Structures are made by metal1 tracks situated horizontally along the whole of the structure. These tracks are connected to the Sources (10) and the Drains (13) (FIG. 8) of the structure by the greatest number of connections metal1/diffusion allowed by the technology layout rules, which connect with the respective N⁺ diffusions. This methodology is intended to reduce contact resistance and to achieve a uniform distribution of current along transistor terminals. In order to connect the metal2 tracks (4) at right angles to the metal1 tracks, there are between five and seven groups of an appropriate number of vias (15) (FIG. 8), associated in the manner permitted in technology, in order to accommodate the maximum current handled by the structure. The horizontal connections of adjacent arrays and/or of matrix external arrays are made by sets of vias (16E) situated at the end of the metal 1 tracks at both sides of the structure (FIG. 7b)). The Gate connections have at least two vias (16P) (FIG. 7a)), thus creating a redundancy which makes this connection more robust and less resistive. The Drain (16D) and Source (16F) connections (FIG. 7a)) have sets of four or more vias with sufficient current capacity in order to drain the maximum current handled by a single NMOS structure.

The connection of the Gates (18) (FIG. 7a) and FIG. 8) of the transistors to the interconnection channels is made at both sides of the structure in order to facilitate the access to the pads and thereby satisfy the technological limitations, which generally do not allow metal1/polysilicon contacts to be placed over the active area of the transistors. There is a redundant metal1 connection over the polysilicon track of the Gate along the structure.

In the quasi-closed ring structure (FIG. 8), the Source of the external transistor (10), as well as the P⁺ diffusion guard ring (11), surround the whole and make it more insensitive to occasional electrostatic discharges, as in the case of input/output protection structures associated to I/O pads. The said guard ring is shared by adjacent Structures in the array (11) (FIG. 8).

There may be additional metal1 tracks between the NMOS Structures, providing an alternative routing for control signal interconnections.

The NMOS Structures used are characterised in that they consist of lateral transistors in which lightly doped regions are inserted, in the path of the current flow in both the Drain and the Source region (by means of a well diffusion with a low concentration of impurities available in the CMOS technological process), in order to reduce the peak value of the electrical field at the surface, beneath the gate oxide. Thus, the pair of elementary LDSD devices used as low impedance pass transistors, both have floating Drain and Source electrodes and are therefore able to withstand a sufficiently high voltage at both terminals in relation to the substrate.

The LDSD NMOS transistors used were optimised considering breakdown voltage by shifting the Gate mask in relation to the lightly doped well mask, which reinforces the reduction of the peak value of the electrical field at the surface. Thus, a device is obtained, derived from the elementary LDSD transistor, known as a GSLDSD, an acronym derived from Gate-Shifted LDSD, used as a low impedance pass transistor which therefore has both of the floating Drain and Source electrodes able to withstand higher voltages in relation to the substrate. This structure is described in detail in the following paragraph.

1.B. -GSLDD/GSLDSD NMOS Transistors

A particular feature of the Gate-Shifted LDD or LDSD (GSLDD or GSLDSD) NMOS transistor is that the Gate electrode is aligned with the path of the lateral diffusion of the N-well (31), as used in CMOS technologies and illustrated in FIG. 9.

FIG. 9 shows the cross-section of an elementary NMOS structure consisting of GS-NMOS transistors, which can be obtained without altering the manufacturing process of any conventional CMOS technology with diffusion of N-wells in a P-type substrate. The Source/Drain (27) consists of an N⁺ diffusion (28) with a high concentration of impurities, typically used for the Drain and Source of the standard NMOS transistors known in technology and diffused in the N-well (26) known in technology, with a low concentration of impurities, normally used as a substrate for the PMOS transistors known in technology, characterised by a concentration of impurities of the same magnitude order, but slightly higher than the concentration of the substrate. Between this N⁺ diffusion (28) and the channel of the device, the carriers cross the drift region underneath the field oxide (29) formed by the process commonly known as LOCOS (Local Oxidation of Silicon), to the end of the metallurgical junction of the N-well diffusion (26).

The geometry of the Gate (32) bestows the originality claimed and allows the proposed devices to breakdown, by avalanche multiplication, at voltage levels much higher than the ones found in both the conventional NMOS transistors and the classic LDSD transistors obtained using the same technologies. The polysilicon Gate (32) is placed over the thin Gate oxide (30), the thickness of which is a few hundred Angstrom. By locating the edge of the Gate (32) at the Source/Drain side (27) (which in classic LDSD transistors is situated exactly at the alignment of the N-well mask) over the lateral diffusion region (31) of the N-well (26), it is possible for the critical electrical field for Silicon, which causes the device to breakdown, to be reached at voltage values higher than the ones obtained for conventional NMOS and classic LDSD transistors. Thus, masks layout of the device, the polysilicon and N-well masks are never in the same line and are separated by what the authors propose to be known as a “Gate-Shift”—which have given rise to the nomenclature proposed for this type of semiconductor device: Gate-Shifted NMOS—GS-NMOS. As the structure under discussion derives from the classic LDSD transistor, the semiconductor device with identical Gate geometry to that which is described above will be hereinafter referred to as Gate-Shifted LDSD NMOS—GSLDSD NMOS.

The greater the distance between the aforementioned masks, the higher the breakdown voltage of the transistor. Provided that the distance in question is not so great that the alignment of the edge of the Gate ceases to overlap the lateral diffusion region (31), which would definitively prevent the formation of a channel. Depending on the technology used, a tolerance of a few hundred nanometers (nm) should be required for the Gate shift, in order to maximise the increase in the breakdown voltage that this technique permits without affecting channel formation in the device.

The geometry of the Drain (35) of the GSLDSD is identical in every way to that of the Source/Drain (27) and a Gate shift may be desired at both the Source/Drain side (27) and the Drain side (35). If the device is symmetric, in cut-off conditions it will present the same robustness in terms of voltage, at both the Drain side and the Source side, which bestows on it the characteristics of a High-Side transistor. It should be noted in constructive terms that the stringent choice of the minimum admissible distance between the adjacent N-wells (26) and (37) is fundamental. The distance between the aforementioned diffusions, which is adjusted in accordance with the distance between the rectangles which define their dimensions in the N-well mask, must be selected in such a way as to avoid device punchthrough.

In NMOS Structures with a Low-Side transistor, the Source of the GS-NMOS device may simply consist of the N⁺ diffusion (39), the transistor being hereinafter referred to as GSLDD NMOS, since it is derived from the classic geometry of the LDD NMOS. Also in this case, the Source terminal (40) can be connected electrically to the substrate (25), by the first metal level in technology, through the terminal (42) connected to a P⁺ diffusion (41) with a high concentration of impurities, habitually used for the Drain and Source diffusions of PMOS transistors known in technology. The maximum voltage admissible at off state for this geometry is identical to that which is obtained for the GSLDSD.

The use of the Gate shift technique implies an increase in the on-resistance of the GSLDSD devices as compared with common LDSD devices, since a longer drift path is required for the carriers between the Drain contact and the edge of the Gate.

In short, the breakdown voltage of the GSLDD/GSLDSD devices is higher than that of the classic LDD/LDSD devices, since the region under the end of the Gate corresponds to a region of concentration of impurities which is even lower than that of the surface of the well—the lateral diffusion of the well. Thus, the electrical field is spreaded, since it is situated in a region, which is even more lightly doped than in the case of the classic devices, providing even higher Drain Source voltage values.

2- Circuits Based on NMOS Structures

The circuits necessary for power control, namely for driving the power devices, typically to perform rectifying, clipping, clamping, regulating, voltage level shifting, charge-pumping and bootstraping functions.

Examples of topologies of these circuits, based on NMOS Structures and claimed as being innovative in the context, are described below. The NMOS Structures basically use the LDSD NMOS transistors described in 1, and topological solutions for constructing the same circuits using LDMOS transistors are also presented.

It should be emphasised that whereas in the LDSD NMOS transistor the body (P type) coincides with the substrate, in the LDMOS transistor the body (P type) is connected to the respective Source and it remains floating, as well as Drain and Source terminals, in relation to the P substrate.

When the NMOS Structure used is based on LDSD NMOS transistors, it will be represented by a symbol with four terminals and the body will be obligatorily connected to the substrate; if it is based on an LDMOS transistor, the fourth terminal (that of the body) will be obligatorily connected to the Source of the transistor. If the functionality of the circuit is independent of the type of transistor, the transistor will be represented by a symbol of three terminals and the terminal of the body of the transistor will be omitted.

2.A - Zener Circuits and Rectifiers

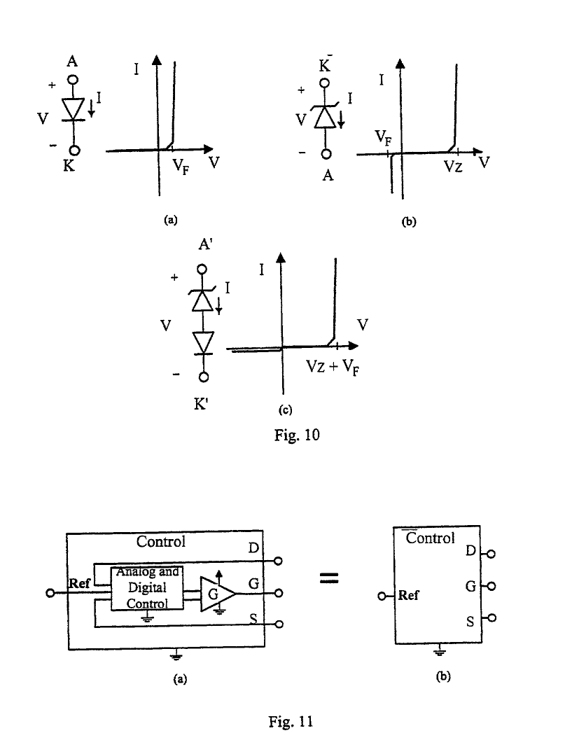

Circuits used for rectifying, clipping, clamping and regulating applications use rectifier diodes or Zener diodes (FIG. 10), the functioning of which can be emulated by NMOS Structures in certain topologies.

The vast majority of NMOS Structures require a Control block (FIG. 11) for activating their NMOS transistors. In many circuit topologies, the parasitic diodes intrinsic to the NMOS Structure are used to perform the desired functions. Control circuits normally contain two circuit blocks: the analogue/digital Control block, which is referred to the ground of the circuit, operates at a low voltage and uses conventional circuits and control techniques; and the output block of the Control circuit, which is a G-gain amplifier and may contain either low-voltage or high-voltage transistors and supplies the voltage and current levels appropriate for operating the circuit. FIG. 11a) and b) shows in diagram form the control described above.

2A.1- Zener Circuit

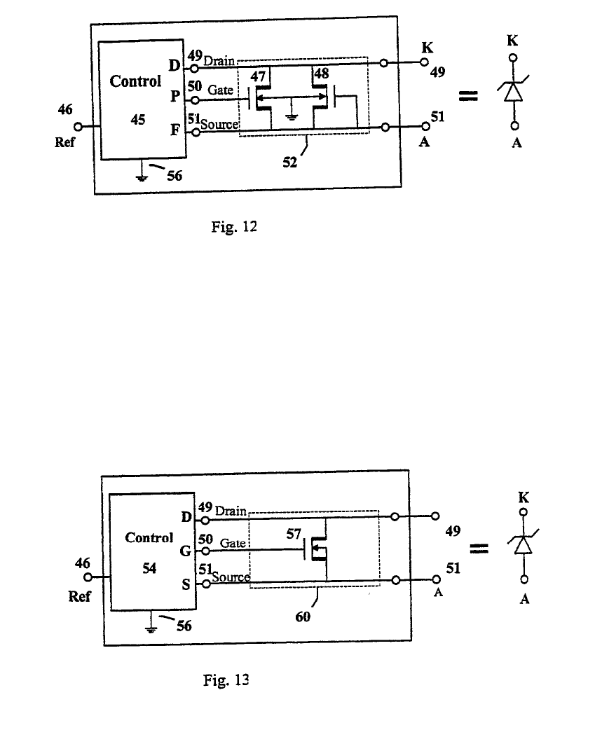

The Zener Circuit (FIGS. 12 and 13) performs functions equivalent to those of a Zener diode implemented with PN junctions (FIG. 10b)). The implementation of Zener Circuits with NMOS transistors (LDSD type in FIG. 12 and LDMOS type in FIG. 13) consists of associating the Drain (49), Gate (50) and Source (51) terminals of an NMOS Structure (52/60) to an electronic Control circuit (45/54) referred to ground (56). It should be noted in general that the control circuit used for an LDSD structure would be different from the one used for an LDMOS structure. However, the operating principle is similar and will be described below for the LDSD transistor.

The behaviour of the Control Circuit (45) is programmable and acts in such a way as to control the value of the voltage between the Gate—G (50) and the Source—S (51), thereby limiting the value of the voltage between the Drain D (49) and the Source—S (51) of the Structure (52) to the desired value of the Zener voltage. The programming of this value for the Zener Circuit is carried out by applying an analogue or digital reference signal, Ref, as a voltage or current, at the reference input of the Control (46).

The control operates by monitoring the voltage existing between the Drain (49) and the Source (51) and it acts on the Gate (50) of the Structure, thereby controlling the on-resistance of the NMOS transistor (47). When the voltage V_{DS} between the Drain (49) and the Source (51) exceeds the programmed value, the control increases the conductivity of the transistor (47) in order to keep the V_{DS} to the pre-defined value. For V_{DS} values lower than the value programmed in the control, no power is dissipated in the NMOS Structure (52) and the current in the Zener circuit takes on a minimum value, which will be the same as the bias current of the control circuit.

2.A.2- Rectifying Circuit

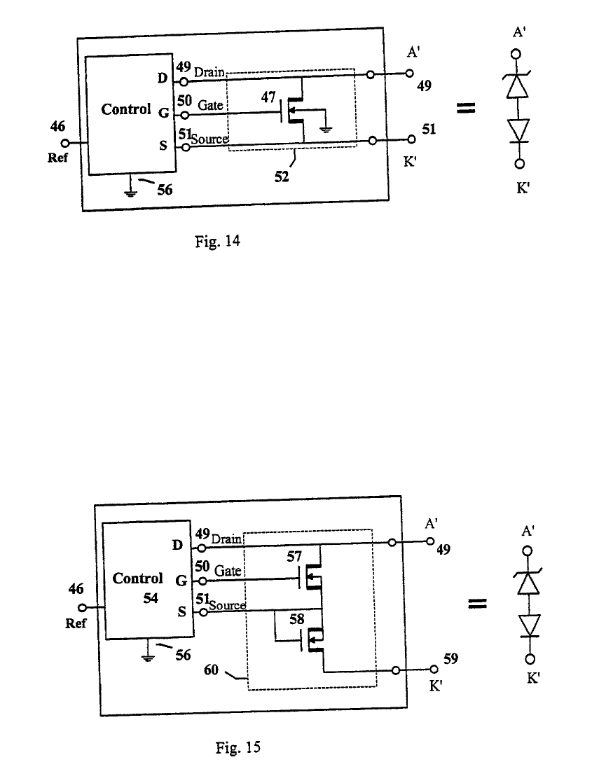

The behaviour of a rectifier diode and of the rectifier diode—Zener diode association (FIGS. 10a) and 10c)) is emulated by the Clipping Circuits of FIGS. 14, 15, 16 and 17, provided that the dimensions of the transistors of the NMOS Structures (52) and (60) are correct.

The behaviour of the rectifier diode—Zener diode series association of FIG. 10c) is reproduced using a Control unit (45) which contains an amplifier (G) and a monitoring and control circuit (FIG. 11). The circuit is implemented associated to an NMOS structure (52), based on LDSD NMOS transistors as shown in FIG. 14, and based on LDMOS transistors in FIG. 15 for an NMOS structure, which in this case uses a similar control unit (54).

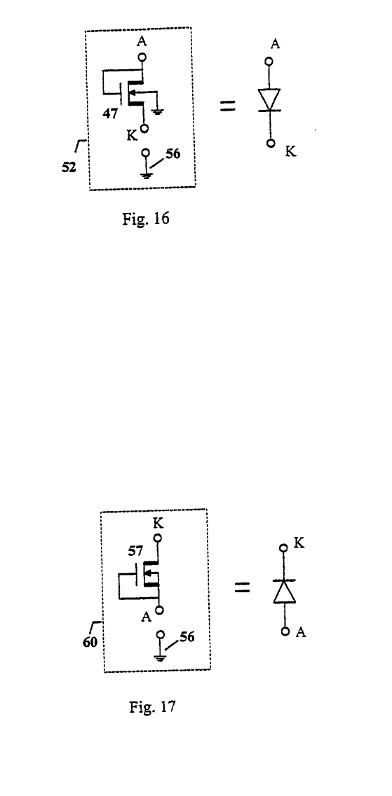

The NMOS structure (52) based on LDSD type NMOS transistors must be floating and operating within the limits of the specifications. The Drain, Gate and Source terminals of the transistors in the NMOS Structures configured as a diode must always operate with positive voltages in relation to the ground terminal GND (56). The driving circuit G, inside the Control (45), acts to reduce NMOS structure (52) impedance by means of the application of an adequate voltage between the Source (51) and the Gate (50), controlled by the voltage between the equivalent Anode (A′) (49) and the equivalent Cathode (K′) (51). In fact, when the A′ voltage (49) is greater than the K′ voltage (51), the circuit operates by emulating of a forward biased diode; when the A′ voltage (49) is lower than the K′ voltage (51), the control circuit acts in such a way as to cause the transistor (47) to cut off, being equivalent to a diode under reverse bias. For many applications in which the diode effect is intended, the G-gain control circuit (45), which operates at a low voltage, is dispensed with and is reduced to a short circuit between the Drain (49) and the Gate (50) or the Drain (49) and the Source (51), as shown in FIGS. 16 and 17.

2.B - Level shifters

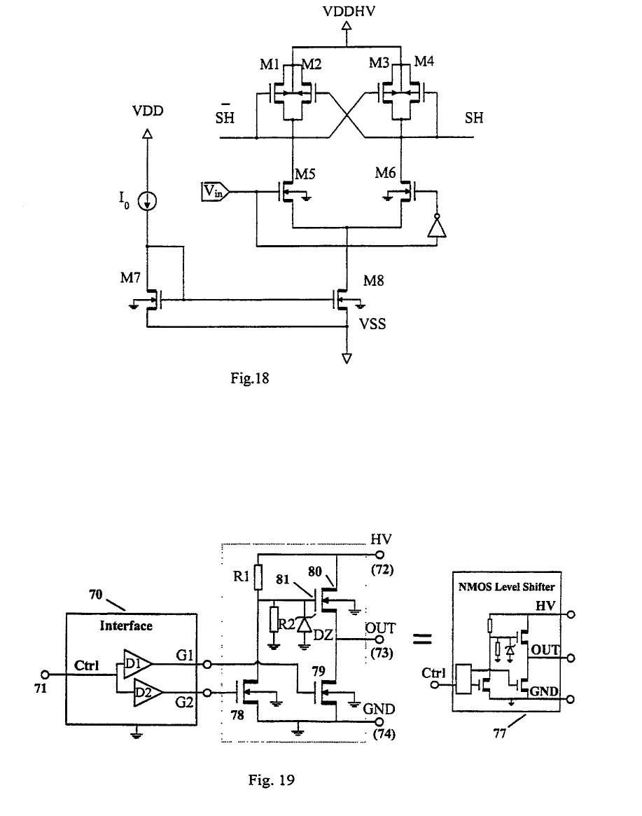

Level shifters, which are used frequently in Smart Power, such as the circuit presented in FIG. 18, use high-voltage PMOS or PNP and NMOS or NPN transistors. The low impedance paths are activated alternately.

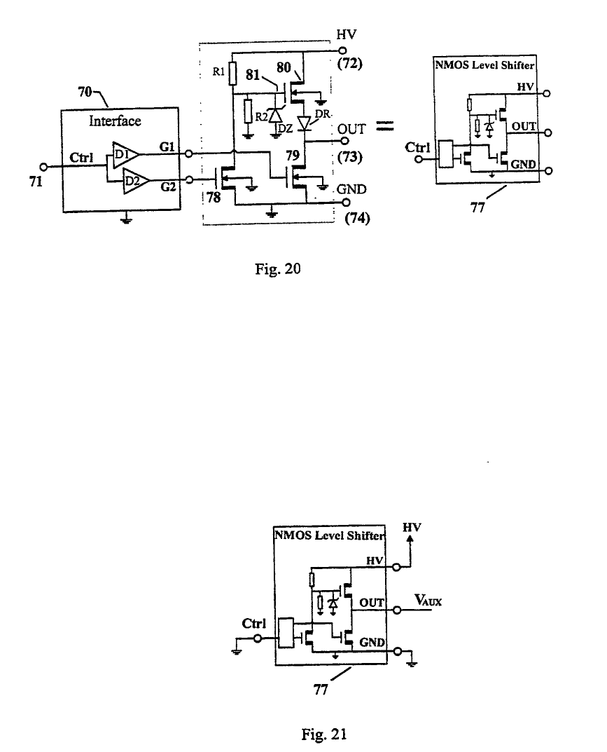

The topologies claimed, which emulate level shifters, only use NMOS Structures to provide the two low impedance paths, as shown in FIGS. 19 and 20, and contain NMOS transistors (78, 79 and 80), resistors R1 and R2, a Zener diode DZ and a rectifier diode DR. The elements R2 or DZ or DR, or a subset thereof, can be eliminated in certain configurations, thus creating certain circuit variants suitable for a specific application.

The control signal (71) acts on the D1 and D2 circuits of the interface (70) to drive the high-voltage transistors of the NMOS structure (78) and (79). The values of the relative delays and the maximum current and voltage values in D1 and D2 are specified in each design in accordance with the application. In some applications, D1 and D2 of the Interface block (70) can be placed in parallel to one another and are used as a single interface circuit (G1=G2).

This paragraph describes the operation of the circuit of FIG. 19. When the control signal (71) is at logic level “1”, the transistors (78) and (79) are in conduction and the transistor (80) is in the off state, since the voltage at its Gate (81) is practically at ground potential (74). The low impedance OUT path (73) to the ground terminal (74) is provided by the transistor (79). When the control signal (71) is at logic level “0”, the transistors (78) and (79) present a high impedance and the Gate (81) of the transistor (80) is then referred to the lowest value of the voltages HV×R2/(R1+R2) or VZ. The transistor (80) thus forms a low impedance path between the HV terminal (72) and the output terminal OUT (73) of the circuit. This applies to output voltages OUT (73) lower than HV×R2/(R1+R2)−V_{T}(80) or V_{Z}−V_{T}(80), in which V_{T}(80) is the threshold conduction voltage between the Gate and the Source of the transistor (80).

This paragraph describes the functioning of the circuit of FIG. 19 in the configuration in which the element R2 is removed from the circuit. When the Cathode of a Zener diode or Zener circuit, represented as DZ in FIG. 19, is connected between the Gate (81) of the transistor (80) and the ground GND (74), the circuit operates in a similar way to that which is described above and the final value of the OUT voltage (73) will be limited to V_{Z}−V_{T} (80) and will be independent of the HV value of the supply voltage (72) (for HV values higher than V_{Z}).

If the resistor R2 and DZ are specifically excluded from the circuit, the maximum final value of the output voltage OUT (73) will be limited to HV−V_{T} (80). The value of the final voltage under the conditions described above will thus be defined by the HV supply voltage (72).

The circuit topologies claimed herein can be constructed using high-voltage NMOS transistors of the type LDSD NMOS (FIG. 19) or LDMOS (FIG. 20). Level shifter circuits constructed with LDMOS transistors also contain the diode DR in their topology. The inclusion of this element is necessary so that both of the topologies presented in FIG. 19 and FIG. 20 operate in the same way, thus permitting the existence of voltages higher than HV at the OUT terminal (73) when the transistor (79) is in the off state.

Although the value of the final OUT voltage (73) of the circuits claimed is slightly lower than the circuits constructed using PMOS or PNP transistors in the High-Side position (see FIG. 18), they can nevertheless be used in the vast majority of applications which require a level shifter circuit. The possibility of programming the maximum final output voltage of the topology claimed, as explained above, is an advantage in relation to the conventional topology presented in FIG. 18.

The Level Shifter circuits (77) presented in FIG. 19 and FIG. 20 can also operate as level shifters for continuous voltages, as shown in FIG. 21. For example, if in a particular configuration the control signal (71) is permanently connected to GND (74), the OUT value will be limited to the voltage value programmed in the Zener Circuit or proportional to HV, as previously presented. In this configuration, the circuit operates as a continuous auxiliary voltage source derived from HV. This configuration can be used as an auxiliary power supply in charge-pump circuits and bootstrap circuits, as will be demonstrated in 2.C.1 and 2.C.2.

2.C - Driving Circuits

2.C.1- Capacitive Charge-Pump Circuits

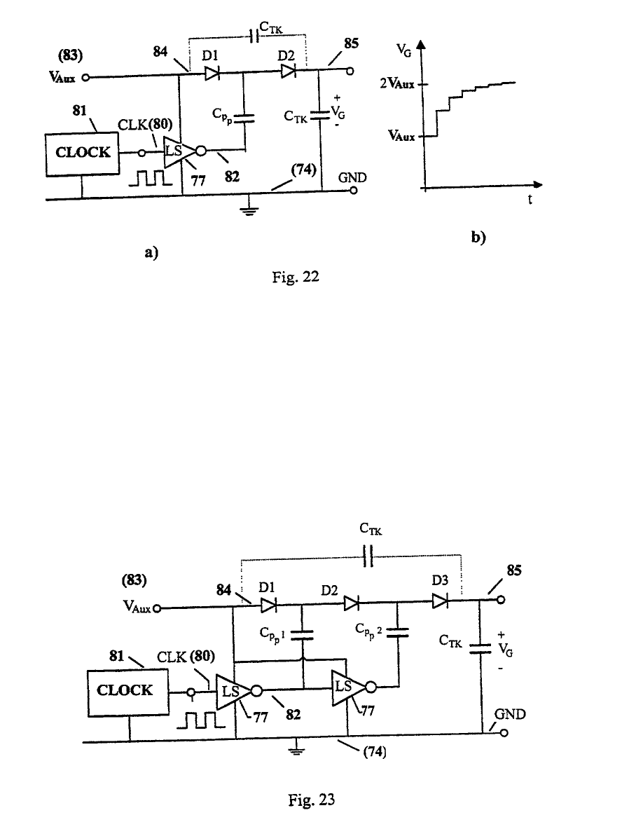

The operating principle of capacitive charge-pump circuits is exemplified in FIGS. 22 and 23. The basic circuit of FIG. 22a) contains at least two rectifiers, two capacitors and an LS (Level Shifter) interface circuit (77), fed by an auxiliary voltage source V_{Aux}. The input signal Clk (80) at the input of the LS interface (77) comes from an oscillator (81) which normally generates a square wave with a low amplitude. The output signal (82) of the LS interface circuit (77) is established in accordance with the dimensions of the circuit and the characteristics of the NMOS Structure used and its value will be lower than or equal to V_{Aux}. The capacitor C_{Tk} can be connected between the terminals of the association of rectifier diodes (84) and (85), represented by a dotted line, or between the output (85) and the GND Terminal (74), depending on the application.

FIG. 22b) represents a transient response (volt vs. second) of a circuit, which uses ideal components, i.e. LS interface with nil saturation voltage and ideal rectifiers. In this case, after a few pump cycles, the voltage at the C_{Tk} terminals, V_{G} tends towards the value 2V_{Aux}. This type of circuit is known as a voltage doubler circuit and is frequently used in both discrete and integrated circuits.

In order to design a charge-pump circuit in the most accurate way possible, it is necessary to consider the value of the Drain-Source voltage of the NMOS transistors (79) and (80) (FIG. 20) of the LS interface (77), the voltage drop in the rectifier diodes, the charge loss of the capacitors and the losses in the connections between the components. Normally, the LS interface circuit (77) is fed by an auxiliary source V_{Aux}, (83) derived from the high voltage supply HV, which provides a voltage value adequate for enabling the LS interface (77) to vary the signal at its output (82) in order to charge C_{Tk} in the quickest and most efficient way possible.

The LS interface circuits constructed with high-voltage devices, as shown in FIGS. 19 and 20, can be fed directly by the high voltage supply HV or by an auxiliary source V_{Aux} derived from HV, as exemplified in FIG. 21. These circuits have a greater variation of output amplitudes (82) as regards the LS interface (77) and they require lower capacity values compared to circuits built with logic CMOS cells. In these circuits, the semiconductor devices can be designed in such a way that the output voltage of the LS interface (77) can take account of the specific nature of the final output voltage V_{G} of the charge-pump circuit.

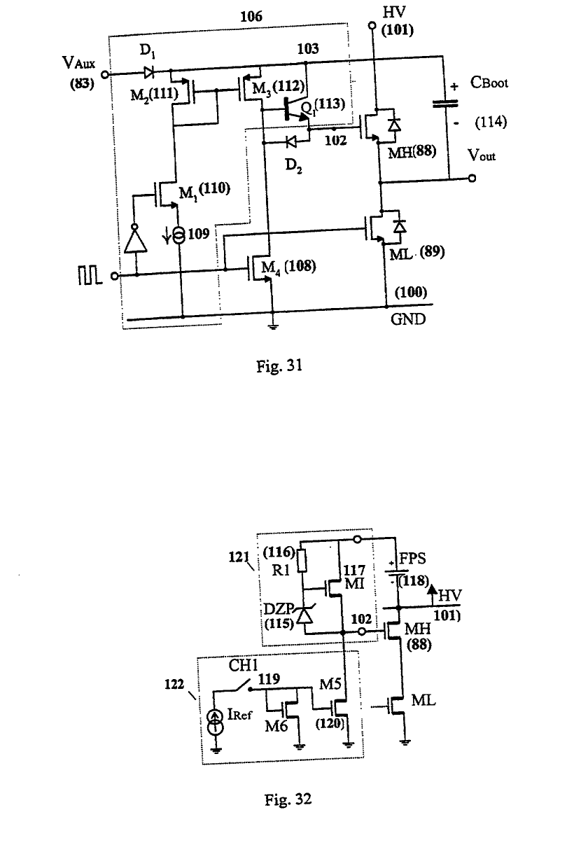

Circuits containing multi-stages implemented using this principle have a final voltage value V_{G} which will ideally be the same as the number of stages plus one more multiplied by V_{Aux}. These circuits are commonly known as voltage multipliers. FIG. 31 represents a voltage tripler circuit. When compared with the circuit of FIG. 22a), this circuit contains an additional stage consisting of a level shifter LS (77), a diode D3 and an additional capacitor C_{Pp2} and it operates in a similar way. For a circuit constructed with ideal components, the final value of VG is 3×V_{Aux}. With real components, V_{G} will be slightly lower, owing the losses mentioned above.

The circuits of FIG. 22a) and FIG. 23 were used to describe the operating principle of charge-pumps circuits. A charge-pump circuit can be configured as a floating power supply. The Anode of the diode D1, disconnected from V_{Aux}, becomes the (−) pole of the floating power supply FPS and the Cathode D2 of FIG. 22a), or the Cathode D3 of FIG. 23, becomes the (+) pole. The capacitor C_{Tk} can be connected between the (−) pole (84) and the (+) pole (85) of the supply or between (85) and (74). This type of circuit (FPS) is frequently used to generate a voltage higher than the supply voltage of the high-voltage circuit and to supply the current sources that are used to inject current into the Gate of the NMOS power transistors configured as High-Side or Low-Side, as will be explained in 2.C.2.

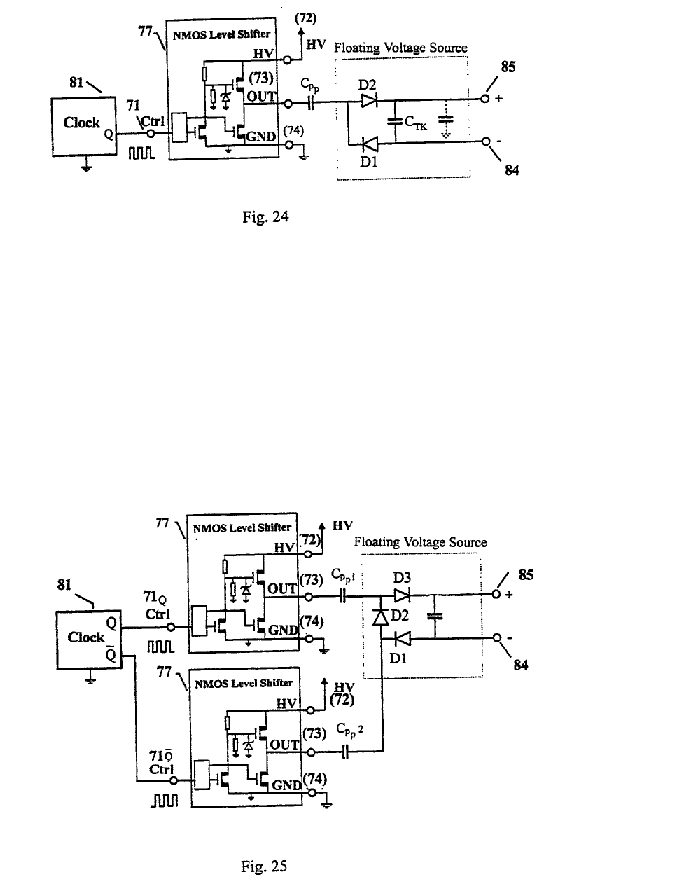

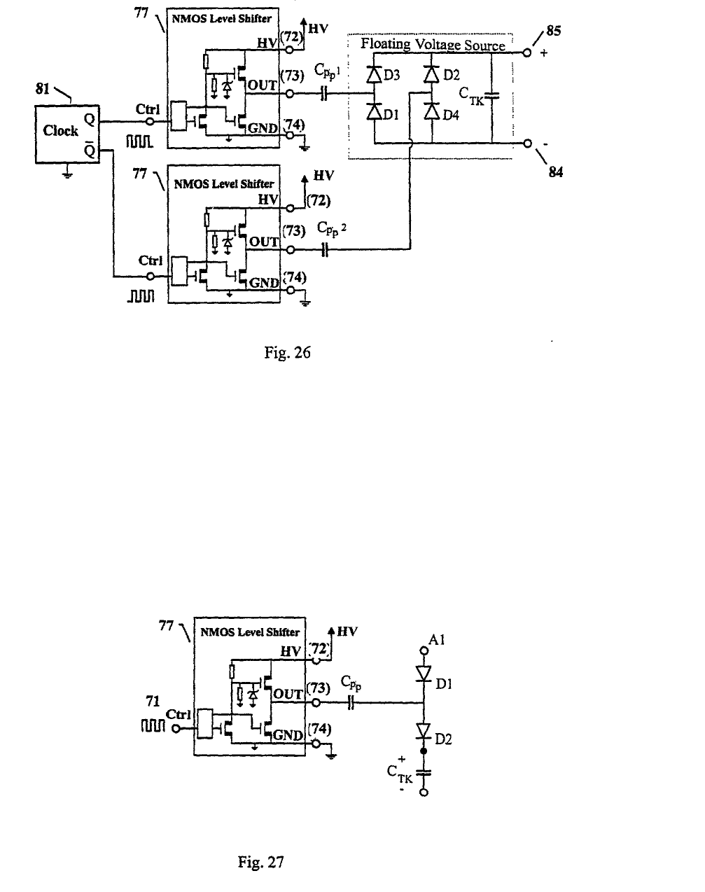

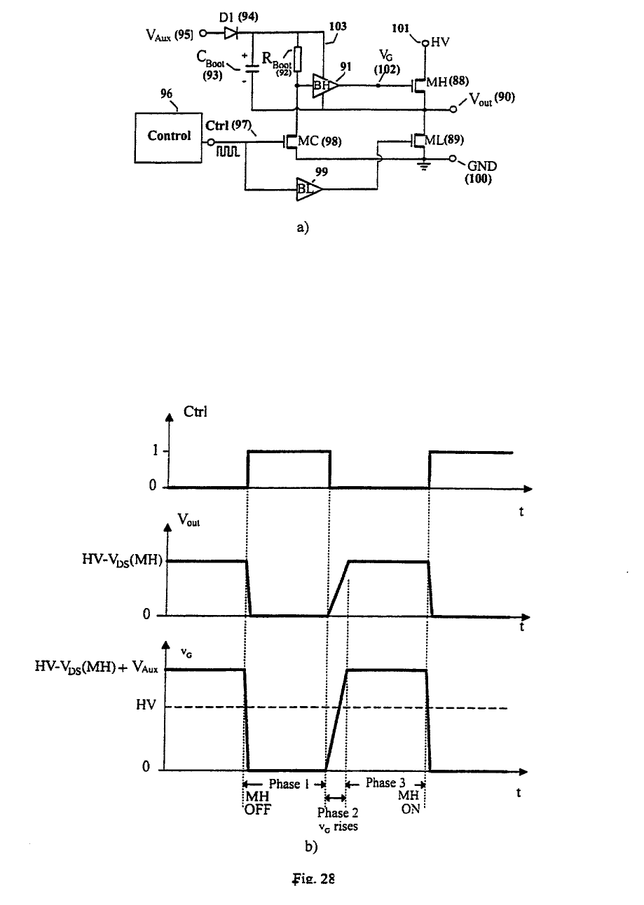

FIGS. 24, 25 and 26 present some of the topologies claimed in this patent, which act as a floating power supply and only use NMOS Structures: the rectifier diodes and Zener diodes are constructed as described in 2.A; the interface circuits used are the ones presented in 2.B and 2.C. The capacitors may or may not be integrated. Basically, these circuits use level shifter circuits constructed with NMOS Structures, containing LDSD or LDMOS NMOS transistors. The elementary structure is that of FIG. 27, from which the charge-pump circuit topologies that are claimed can be easily, obtained.

2.C.2- Capacitive Bootstrap Circuits

FIG. 28a) shows the typical electrical layout of a Capacitive Bootstrap Circuit mentioned in literature. This circuit consists typically of a C_{Boot} capacitor (93), BH (91) and BL (99) interface circuits (Buffer High-Side and Buffer Low-Side respectively), an R_{Boot} resistor (92), a control transistor MC (98) and two power transistors, ML (89) and MH (88). Its operation is based on the storage of electric charge in the C_{Boot} capacitor (93) in order to maintain an adequate voltage to its terminals. Thus a floating supply to the BH circuit (91), which acts as a driving circuit for the NMOS power transistor MH (88), thus controlling its ON-state. The Drain of the transistor MC (98) and one of the R_{Boot} terminals (92) are connected to the input of the BH interface (91) and they form a level shifter. The (−) terminal of the floating voltage source formed by the C_{Boot} capacitor (93) is connected to the Source terminal (90) of the transistor MH (88). The supply voltage V_{Aux} (95) is normally higher than the supply voltage of the logic circuit and can be lower than the voltage of the high-voltage power source, HV (101), which supplies the output level consisting of the pair of Power Transistors MH (88) and ML (89). The value of V_{Aux} (95) can be generated from the high-voltage power source, as described in 2.B, and it must be in accordance with the voltage value that is intended to be applied to V_{GS} (MH) (102) in order to achieve full conduction of MH (88).

The capacitive bootstrap circuit is commonly used in applications where the control signal Ctrl (97) is periodic, with a defined operating frequency. In order to describe the functioning of this circuit, the period of the control signal Ctrl (97) of FIG. 28b) is considered to be divided into three distinct phases, the state of the circuit being described for each phase.

Phase 1: Charge of the C_{Boot} capacitor

During this phase the Control signal Ctrl (97) is at a high level and ensures the conduction of MC (98) and ML (89). During this phase, C_{Boot} (93) is charged with approximately the V_{Aux} voltage value (95) through the D1 diode (94). While MC (98) is conducting, the BH interface (91) keeps the High-Side transistor MH (88) disconnected and ML (89) forms a low impedance path Vₒᵤₜ (90) to the circuit ground (100), thus allowing C_{Boot} (93) to be charged

Phase 2: Start of the Bootstrap Action.

This phase is characterised by the change of state imposed by the control signal Ctrl (97), which changes from logic level from “1” to “0”. At this stage, the ML (89) and MC (98) transistors are disconnected and the signal at the input of the BH interface (91) remains at the potential of the (+) terminal of C_{Boot} (93) and therefore the output signal (102) of the BH Interface (91) is referred to this voltage, taking the MH transistor (88) to the conducting state. The voltage Vₒᵤₜ (90) increases according to the current which flows in the load until it reaches the final value of HD-V_{DS} (MH). The voltage to the terminals of the C_{Boot} capacitor (93) is kept virtually constant during the conduction time of MH (88) and the voltage value in the Gate of MH (88), V_{G} (102), reaches approximately HV-V_{DS} (MH)+V_{Aux}. During this period, the diode D1 (94) is inversely polarised and isolates the power source Vₐᵤₓ (95).

Phase 3: Free Conduction of MH.

During the next phase the transistor MH (88) starts free conducting. While MH (88) is in conducting state, C_{Boot} (93) discharges through the current supplied to the driving circuit (91) of MH (88). The maximum duration of this phase is determined by the length of time for which the C_{Boot} capacitor (93) manages to maintain a voltage adequate for supplying the BH interface (91), which in turn maintains the voltage at the Gate of MH (88), thus allowing MH (88) to continue conducting. It should be noted that the discharge of the C_{Boot} capacitor (93) is due to the charge transfer to the Gate of MH (88) and to the losses caused by the parasitic elements. Normally the dimensions of C_{Boot} (93) are designed to allow its voltage to be reduced by only 10% during the work cycle.

The circuit presented in FIG. 28a) is suitable for applications where the operating frequency is well defined, as it is necessary to define the appropriate value of C_{Boot} (93) for each circuit and the respective operating frequency. This technique has the advantage of being simple and it allows MH (88) to be commuted at a high frequency using a small number of high-voltage components. However, it is limited to a small number of applications, as there may be an undesirable situation in which both ML (89) and MH (88) are conducting at the same time. Circuits derived from this one, but with a more elaborate control, can avoid simultaneous conduction and are the ones that are most often used for commuting associated transistors in High-Side full-bridge and half-bridge configurations [13].

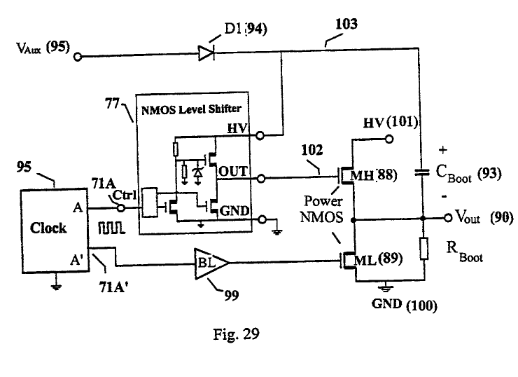

FIG. 29 presents a topology which is different from the circuit of FIG. 28 claimed as being innovative in this patent, which only uses NMOS transistors. The NOS Level-Shifter block (77) presented in 2.B provides the functionality required of the BH interface (91) of FIG. 28a). The control circuit (96) of the bootstrap of FIGS. 28a) and 29 can be programmed to cause delays suitable for driving MH (88) in relation to the driving of ML (89) in order to avoid the simultaneous conduction of the two. The diode D1 (94) can be made as described in 2.A or by using a PN junction in processes where there are diodes able to withstand high voltage.

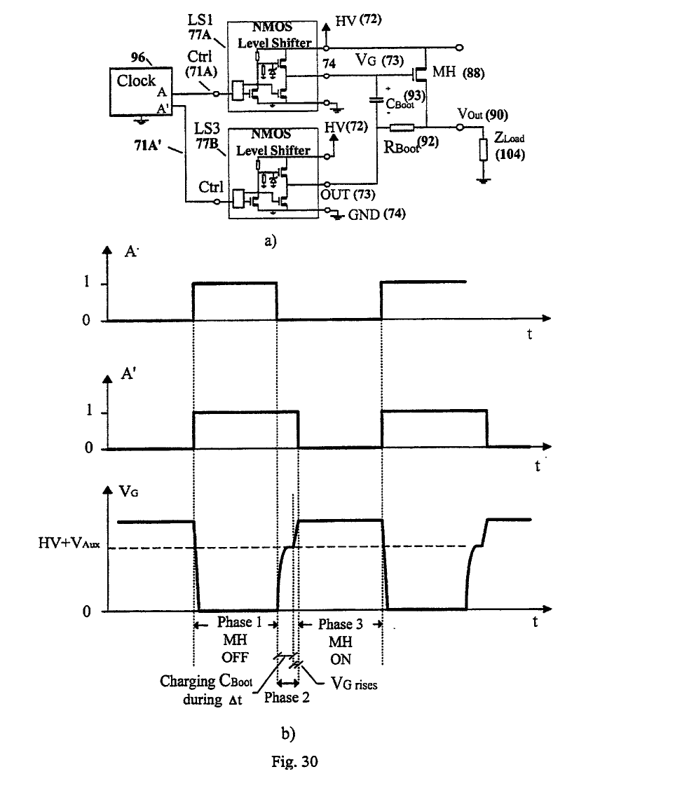

FIG. 30a) presents another topology for constructing a Capactive Bootstrap Circuit for controlling the conduction of the NMOS power transistor MH (88). The construction of the circuit requires a C_{Boot} capacitor (93), an R_{Boot} resistor (92) and two level shifter interfaces LS1 (77A) and LS2 (77B), for example the level shifters (77) described above in 2.B. For this application, the interface LS1 (77A) is programmed to reach the final voltage of V_{Aux} (95), which is the value that should be applied to V_{GS} (MH) for the full conduction of MH (88). The interface LS2 (77B) is programmed so that its output voltage varies up to the closest possible value to HV (72) (101, in FIG. 8a)), which supplies both the Drain of MH (88) and the interfaces LS1 (77A) and LS2 (77B). FIG. 30b) presents the time diagram of the control signal Ctrl (71) and of the output voltages Vₒᵤₜ (90) and the Gate voltage (73) (102, FIG. 28a)) of MH (88) during a connection and disconnection cycle of MH (88). For the purpose of analysis, the cycle was divided into three phases, as previously.

During Phase 1 the transistor MH (88) is disconnected. The signals A (71A) and A′ (71A′) at the input of the interfaces LS1 (77A) and LS2 (77B) are simultaneously at level “1”, their output being lowered to ground potential (74) (100, in FIG. 28a)). The voltage between the Gate (73) and the Source (90) of MH (88), V_{GS} (MH), is practically nil and there is no current flowing in the charge Z_{Carga} (104).

During Phase 2 there are two distinct stages. The first stage corresponds to the charge of the C_{Boot} capacitor (93). This occurs straight after the transition of the control signal A (71) from level “1” to level “0”. At this stage, the output of the interface LS1 (77A) provides energy to charge the C_{Boot} capacitor (93) up to the voltage level programmed in LS1 (V_{Aux}), as described in 2.B. Simultaneously, the capacitor equivalent to the capacitive effect between the Gate and the Source of the transistor MH (88) is also charged through the output of the interface LS1 (77A). The signal A′ (71A′) remains at logic level “1” during a period of time Dt sufficient for charging C_{Boot} (93) through LS1 (77A) and LS2 (77B) and for reaching the voltage value defined for the layout, V_{Aux}, which causes MH (88) to conduct. After the period of time Dt, the signal Ac switches from level “1” to level “0”, thus initiating the second stage of this phase, which is characterised by the of the voltage V_{G} (102). The (−) terminal of C_{Boot} (93) is then referred to the potential existing at the Source of the transistor MH (88) through the P_{Boot} resistor (92). Thus, the V_{GS} voltage (MH) will be practically the same as the voltage existing in C_{Boot} (93) and the HV Source (72) then supplies the maximum current to the charge Z_{Carga} (104) through the transistor MH (88).

Phase 3 of the functioning of this circuit is characterised by the fact that the signals A and Ac remain at logic level “0” after the voltage V_{G} (73) reaches its final value of approximately HV+V_{Aux}, as shown in FIG. 30b). This phase lasts until the control signals A (71A) and A′ (71Ac) simultaneously transition from logic level “0” to logic level “1”, thus causing the C_{Boot} capacitor (93) to discharge and the transistor MH (88) to cut off, which characterises the initial state for a new cycle. It should be noted that the output level of the level shifter circuits LS1 (77A) and LS2 (77B) used is achieved using NMOS transistors which allow the output voltages to reach a value greater than the HV supply voltage (72) of the interfaces.

A transistor ML (89) can be added to the circuit of FIG. 30a), connected between the Source (90) of MH (88) and the ground GND (74) in a Low-Side configuration, directly controlled by the control circuit, as in the case of the circuit of FIG. 29.

2.D - Floating Current Source

Current sources are often used to control the charge and discharge of the equivalent input capacitor C_{GS} of power transistors, which feed the external load. Circuits which use current sources as a way of controlling the injection and drainage of the charge in C_{GS}, in order to cause the transistor to both conduct and cut off, permit control and switching using algorithms optimised according to the type of charge which is intended to be supplied. In manufacturing technologies dedicated to the integration of smart power devices, which produce high-voltage NMOS and PMOS transistors, the creation of current sources to supply High-Side transistors is facilitated by the existence of the high-voltage PMOS transistor.

FIG. 31 shows a typical circuit which uses a floating current source (106) to inject current into a High-Side topology power device (88), bringing it to a conducting state. Another current source referenced to the ground, whose output level consists of the transistor M4 (108) is used to drain the current from the Gate of MH (88), thus causing it to cut off.

A current source constructed in MOS technology basically consists of controlling the V_{GS} voltage applied to a transistor. When this transistor is operating in the saturation region, its drain current will depend almost exclusively on V_{GS}. Typically, the reference current source is created with analogue circuits constructed with low-voltage transistors connected to the GND terminal (100). The current generated in (109) is mirrored or copied by circuits constructed with N-type (108 and 110) and P-type (111 and 112) MOS transistors and the NPN bipolar transistor (113), which operate at a high voltage. In the circuit shown in FIG. 31, the C_{Boot} capacitor of a bootstrap circuit, as described in 2.C, is used as a floating power supply—FPS—to feed the current source (106). Another option would be to use a capacitive charge-pump circuit previously presented in section 2.C.1.

This patent claims topologies for current sources with the function of injecting or draining current in both High-Side and Low-Side transistors constructed exclusively with NMOS Structures. Of the various possible topologies, FIG. 32 presents a topology intended to act as a current source circuit by injecting current into the Gate of an NMOS transistor, MH (88), with a High-Side configuration.

As seen above in point 2.A, it is possible to construct circuits, which emulate the behaviour of a floating Zener diode using NMOS Structures. The value of the Zener voltage of these circuits can be programmed dynamically using a control circuit, which functions at a low voltage. It was also shown in 2.B that it is possible to construct floating power supplies using only NMOS Structures.

In FIG. 32 the block components (121) form a floating current source based on NMOS Structures. The output of the current source (121) is connected to the Gate (102) of MH (88) and is used to inject current bring MH (88) to a conducting state. The circuit referenced to the ground (122) implement a current source (100), the purpose of which is to drain current from the Gate (102) of the transistor MH (88), causing it to cut off.

The floating current source (121) basically consists of a Zener circuit represented by DZP (115), a high-voltage transistor represented by MI (117) and a resistor R1 (116). These components are fed by a floating power supply (118), referred to as FPS, whose (−) terminal is connected to the high voltage supply HV (101). The FPS power supply (118) has an amplitude of around ten volts. The component DZP (115) represents a programmable Zener circuit with the control referenced to the terminal GND (100), the function of which is to maintain the V_{GS} voltage (M1) (117) at a certain programmed value, thereby controlling the injection of current into the Gate (102) of the transistor MH (88), according to the algorithm specified for the application. It is important to emphasise that the control exercised over the Zener circuit (115) determines the value of the current, which flows in MI (117). In particular, it is possible to generate a voltage value in the Zener circuit DZP (115) that does not allow the current to flow in MI (117). The resistor R1 (116) must typically have a high value and its function is to polarise the DZP circuit (115) and set the floating current source (121) at the potential resulting from the sum of the voltages HV+V_{(FPS)}.

During the injection of current into the Gate (102) of the transistor MH (88), the transistor MI (117) acts as a current source, the switch CH1 (119) of the block (122) is open and the transistor M5 (120) does not have any influence on the Gate of MH (88). During the draining of current from the Gate (102) of the transistor MH (88), the value of DZP (115) is adjusted in order to reduce or annul the flow of current in MI (88). The current source (122) referenced to the ground is activated when MH (88) is to be cut off (88). The switch CH1 (119) is turned off and the transistor M5 (120) starts to drain the current from the Gate (102) of MH (88), thereby causing it to cut off, as desired.

1. A versatile and programmable Smart Power IC, to provide switching power cells, their drives and protections and other required circuits to control, amplify and sample output variables to meet a wide range of applications requirements, characterized by:
a) comprising Arrays aimed at Power Integrated Circuits (PICs), containing “intelligence” or not, based on the association of NMOS FETs, wherein said, NMOS structures, using a specific layout in a simple pattern, enabling to perform different functions required by Smart Power ICs;
b) providing novel circuit Topologies to enable the control and power signals processing of PICs resorting only to wherein said NMOS structures in association with passive components within the same monolithic circuit or external to it;
c) using wherein said NMOS based Basic Cells, which make use of an association of FETs, such as LDD or LDSD-NMOS or both, or LDMOS or N channel DMOS.

2. A Smart Power IC as defined in claim 1 implemented by wherein said Mask Programmable Smart Power Array by means of:
a) top metal masks layout, which define the semi-custom array NMOS structures interconnections;
b) novel Topologies of the required circuits aimed at power signals processing, using wherein said NMOS structures associations interconnected to define specific functions to be added in Cell libraries, to be used towards a wide range of applications; and
c) complete mask layout to define the NMOS based elementary associations, that support system built-up.

3. A Smart Power IC as defined in claim 1, the circuits topologies of which are obtained through appropriate configuration of the wherein said Mask Programmable Smart Power Array as defined in claim 2.
These circuits include:
a) said rectifiers and wherein said programmable “Zeners”, required in NMOS based clippers and clampers;
b) wherein said NMOS based level-shifter;
c) wherein said NMOS based charge-pump; and
d) wherein said NMOS based bootstrap;
e) wherein said NMOS based current source; including appropriate design methodologies and simulation models.

4. A Smart Power IC as defined in claim 1, characterised by elementary associations, only resorting to a set of NMOS transistors either of LDD or LDSD type, or both, or LDMOS or DMOS, which include:
a) flexible interconnection of the whole set of NMOS structures terminals;
b) a P⁺ guard ring connected to the substrate, involving the elementary cell;
c) connection of LDD type transistors Sources to the referred guard ring;
d) floating LDSD and LDMOS type transistors Sources;
e) specific layout to:
permit local interconnections of Drain, Gate and Source terminals;
make easy the implementation of interconnections through columns between the elementary cells; and
make easy the association of elementary cells in order to obtain more complex circuits, through appropriate interconnections.

5. Smart Power Applications resorting to the Array as defined in claims 1 and 2, incorporating “intelligence” or not, and to the novel topologies as defined in claims 2 and 3 to obtain required: power control, switching and their drives; sampling and protection; towards power conversion and amplification. These arrays can be fabricated either in standard CMOS technology or other CMOS technologies that require additional process steps or yet sophisticated Power Integration technologies or specific Smart Power technologies. These arrays can be configurated in order to perform a large set of functions as defined in claim 3, according to methodologies as defined in claim 4, which are able to associate multiple NMOS transistors in specific configurations, in association with passive elements, integrated or not, to permit:
the implementation of a large set of power switching cells presenting different switch topologies—high-side; low-side; pass element; push-pull; halfbridge; full-bridge, n-phases-bridge and other derived topologies;
the implementation of different devices and circuits required for driving the different power switching topologies;
the implementation of sampling and protection circuits required to achieve a good performance of the power switching cells;
to increase the robustness of smart power ICs with respect to electrostatic discharges and latch-up behaviour; and
the fast prototyping of Smart Power circuits and Microsystems.

6. LDD and LDSD type, N channel, Metal-Oxide-Semicondutor Field Effect Transistors, wherein said Gate-Shifted Lightly Doped Drain—GSLDD and wherein said Gate-Shifted Lightly Doped Source and Drain-GSLDSD, which resort to the wherein said gate-mask shift with respect to N-well mask edge to enlarge breakdown voltage and thus, to expand the application range of wherein said Mask Programmable Smart Power Array as defined in claims 1, 2, 3, 4 and 5, comprising:
fully standard CMOS (N-well, P substrate, one polysilicon layer and at least two metal layer) compatible;
a lateral planar configuration for the wherein said GSLDD, with the said Drain formed by a high impurities concentration diffusion embedded in the low doping concentration N-well;
a connection between said substrate and said source terminals for the wherein said GSLDD;
specific mask layout that allows the said GSLDD drain to handle high voltages;
a lateral planar configuration for the wherein said GSLDSD, with said Drain and Source formed by high impurities concentration diffusions embedded in low doping concentration N-wells;
said source terminals isolated from the said substrate for the wherein said GSLDSD;
specific mask layout that allows both said GSLDSD drain and source to handle high voltages;
the use of the wherein said gate-shifted technique, to obtain the alignment of the said gate mask with the said N-well lateral diffusion periphery path, taking advantage of reduced surface electric field maximum values inherent to low impurities concentration regions, thus increasing device maximum voltage rating.
